(19) United States
(12) Patent Application Publication
(10) Pub. No.: US 2025/0231256 A1
(43) Pub. Date: Jul. 17, 2025

(54) HEALTH CHECK SYSTEM FOR STORAGE CAPACITOR

(71) Applicant: FADU Inc., Seoul (KR)

(72) Inventors: Seonho KIM, Suwon-si (KR); Jinup LIM, Seoul (KR); Kichang JANG, Seoul (KR); Jongchul CHAE, Hwaseong-si (KR)

(73) Assignee: FADU Inc., Seoul (KR)

(21) Appl. No.: 19/022,625

(22) Filed: Jan. 15, 2025

(30) Foreign Application Priority Data
Jan. 16, 2024 (KR) 10-2024-0006744

(51) Int. Cl. G01R 31/64

(52) U.S. Cl. CPC G01R 31/64

(57) ABSTRACT

Disclosed is a health check system for a storage capacitor that checks the status of the storage capacitor without additional discharging in a switching duration of a switching converter that charges the storage capacitor.

### CROSS-REFERENCE TO RELATED APPLICATION(S)

This application claims the benefit under 35 USC 119(a) of Korean Patent Application No. 10-2024-0006744, filed with the Korean Intellectual Property Office on Jan. 16, 2024, the disclosure of which is incorporated herein by reference in its entirety.

### BACKGROUND

### 1. Technical Field

The present disclosure relates to a health check system for a storage capacitor, and more particularly, to a technology of checking the capacitance of a storage capacitor charged by a DC-DC switching converter without an additional circuit and power loss.

### 2. Related Art

In general, a memory system including memory devices and a memory controller operates by receiving power from the outside. Accordingly, when the supply of power to the memory system is unintentionally cut off, data being processed may be lost. In order to cope with such an emergency situation, the memory system includes an auxiliary power supply device. In a steady situation where power is normally supplied to the memory system, the auxiliary power supply device stores energy in a storage capacitor, and in an emergency power situation where the supply of power is cut off, the auxiliary power supply device immediately detects the emergency power situation and supplies emergency power to the storage capacitor by using pre-charged energy.

Since the energy required in the emergency power situation is proportional to the capacity of the storage capacitor and the performance degradation of the storage capacitor, such as a decrease in maximum capacitance, occurs according to an operating voltage, temperature, humidity, use time, and the like, it is necessary to regularly check the capacitance of the storage capacitor. Such a regular check is referred to as a capacitor status check or health check.

In the related art, the capacitor status check for confirming the capacity of the capacitor is performed by discharging the storage capacitor for a certain period of time to determine whether the voltage of the storage capacitor is higher than a threshold voltage. In such a case, an additional discharge circuit is required for the discharging, and power loss inevitably occurs during the discharging process. In addition, since the voltage of the storage capacitor drops during the discharging process and thus the energy of the storage capacitor is consumed, an energy shortage phenomenon may occur in an emergency power situation. Moreover, since a charging circuit needs to operate in order to re-charge the discharged storage capacitor, there is a problem in that efficiency performance is degraded.

In this regard, a method for solving the problem in the storage capacitor status check method in the related art is urgently required.

### SUMMARY

Various embodiments are directed to providing a health check system for a storage capacitor that checks the status of the storage capacitor without additional discharging in a switching duration of a switching converter that charges the storage capacitor.

In an embodiment of the present disclosure, there is provided a health check system for a storage capacitor that checks a capacitance of a storage capacitor charged by being electrically connected to an output terminal of a switching converter that, when a preset level of a charging voltage is a first voltage level, boosts the voltage level to a second voltage level by performing a switching operation according to a switching period, and includes: a switching counter that counts the number of switchings by which the switching operation is performed in a switching duration in which the switching operation is performed; a charging amount calculation unit that calculates an amount of charging per period that is charged in the storage capacitor during the switching period; and a determination unit that determines a status of the storage capacitor based on the first voltage level, the second voltage level, the counted number of switchings, and the calculated amount of charging per period.

In the health check system for a storage capacitor according to an embodiment of the present disclosure, the charging amount calculation unit may calculate the charging amount per period based on current flowing through an inductor of the switching converter and the switching period.

In the health check system for a storage capacitor according to an embodiment of the present disclosure, the determination unit may calculate the reference number of switchings according to Equation 1 below and determine the storage capacitor to be in a steady state when the counted number of switchings satisfies Inequation 1 below.

$$SCr = \frac{Cr \times ( {V}_{H} - {V}_{L} )}{{Q}_{1 period}} \qquad [ Equation 1 ]$$

(in Equation 1 above, SCr is the reference number of switchings, Cr is a preset capacitance of the storage capacitor, V_{H} is the second voltage level, V_{L} is the first voltage level, and Q_{1period} is a charging amount per period)

SCr×α≤SCc≤SCr×β [Inequation 1]

(in Inequation 1 above, SCc is the counted number of switching, α is a rational number equal to or less than 1, and β is a rational number equal to or greater than 1)

In the health check system for a storage capacitor according to an embodiment of the present disclosure, a may be 0.7 to 0.9 and β may be 1.1 to 1.3.

In the health check system for a storage capacitor according to an embodiment of the present disclosure, the determination unit may calculate the capacitance of the storage capacitor according to Equation 2 below, and when the calculated capacitance of the storage capacitor satisfies Inequation 2 below, the determination unit may determine the storage capacitor to be in a steady state.

$$C = \frac{{Q}_{1 period} \times SCc}{{V}_{H} - {V}_{L}} \qquad [ Equation 2 ]$$

(in Equation 2 above, C is the capacitance of the storage capacitor, V_{H} is the second voltage level, V_{L} is the first voltage level, Q_{1period} is the charging amount per period, and SCc is the counted number of switchings)

$$\frac{2 \times E}{{{V}_{L}}^{2}} \leq C \qquad [ Equation 2 ]$$

(in Inequation 2 above, E is preset energy J of the storage capacitor and V_{L} is the first voltage level)

In the health check system for a storage capacitor according to an embodiment of the present disclosure, the determination unit may calculate a required capacitance of the storage capacitor according to Equation 3 below, and “SCr×α” in Inequation 1 above may be determined according to Equation 4 below.

$$Cn = \frac{2 \times E}{{{V}_{L}}^{2}} \qquad [ Equation 3 ]$$

(in Equation 3 above, Cn is the required capacitance of the storage capacitor, E is preset energy J of the storage capacitor, and V_{L} is the first voltage level)

$$SCr \times α = \frac{Cn \times ( {V}_{H} - {V}_{L} )}{{Q}_{1 period}} \qquad [ Equation 4 ]$$

(in Equation 4 above, Cn is the required capacitance of the storage capacitor, V_{H} is the second voltage level, V_{L} is the first voltage level, and Q_{1period} is the amount of charging per period)

The features and advantages of the present disclosure will become more apparent from the following detailed description based on the accompanying drawings.

The terms or words used in this specification and claims should not be interpreted as typical or dictionary meanings, but should be interpreted as meanings and concepts, which coincide with the technical idea of the present disclosure, on the basis of a principle in which the inventor can properly define concepts of terms in order to explain his/her disclosure in a best way.

According to the present disclosure, since the status of a storage capacitor can be checked without additional discharging, no voltage drop occurs, and thus power loss can be prevented.

In addition, since no additional discharging circuit is required, the present disclosure can reduce the size of a circuit and can also be applied to any structure of a switching converter.

In the related art, when additional discharging is performed in a no-switching duration, a voltage may drop to a lower level than a minimum output voltage. However, in the present disclosure, the lowest level is fixed to a minimum output voltage, so that the amount of energy can be stably maintained.

### BRIEF DESCRIPTION OF THE DRAWINGS

FIG. 1 is a configuration diagram of a health check system for a storage capacitor according to an embodiment of the present disclosure.

FIG. 2 is a diagram for explaining a storage capacitor charged by a buck converter in the related art.

FIG. 3 is a diagram illustrating an inductor voltage and an inductor current according to each switch status when the buck converter in FIG. 2 charges the storage capacitor in a current discontinuous conduction mode.

FIG. 4 is a diagram illustrating an inductor voltage and an inductor current according to each switch status when the buck converter in FIG. 2 charges the storage capacitor in a current continuous conduction mode.

FIG. 5 is a diagram illustrating a change in a charging voltage in a switching duration in which a switching operation of the buck converter in FIG. 2 is performed and a no-switching duration in which the switching operation is not performed.

FIGS. 6 and 7 are exemplary circuit diagrams of a health check system for a storage capacitor according to an embodiment of the present disclosure.

### DETAILED DESCRIPTION

The purpose, specific advantages, and novel features of the present disclosure will become more apparent from the following detailed description and preferred embodiments in conjunction with the accompanying drawings. In this specification, when adding reference numerals to components in each drawing, it is noted that the same components are given the same numerals as much as possible even though the same components are shown in different drawings. In addition, terms such as “first” and “second” are used to distinguish one component from another component, and the components are not limited by the terms. Hereinafter, in describing the present disclosure, detailed descriptions of related known technologies that may unnecessarily obscure the gist of the present disclosure will be omitted.

Hereinafter, preferred embodiments of the present disclosure are described in detail with reference to the accompanying drawings.

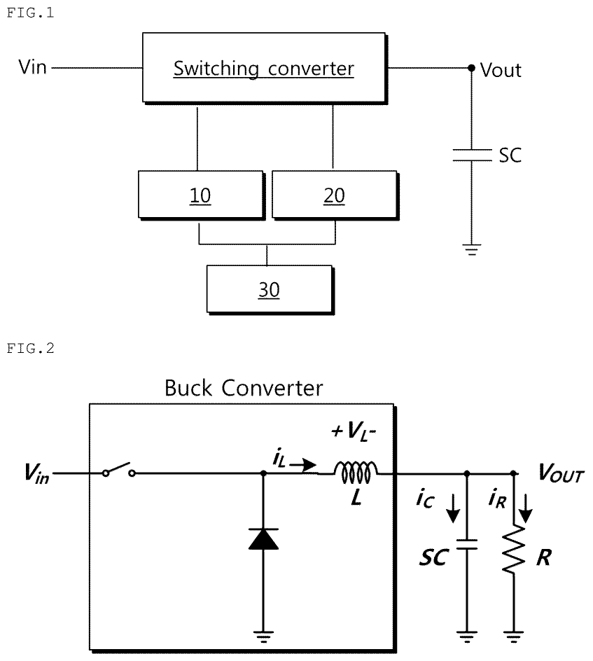

FIG. 1 is a configuration diagram of a health check system for a storage capacitor according to an embodiment of the present disclosure.

As illustrated in FIG. 1, the health check system for a storage capacitor according to the embodiment of the present disclosure checks the capacitance of a storage capacitor SC charged by being electrically connected to an output terminal of a switching converter that, when a preset level of a charging voltage is a first voltage level, boosts the voltage level to a second voltage level by performing a switching operation according to a switching period, and includes a switching counter 10 that counts the number of switchings by which the switching operation is performed in a switching duration in which the switching operation is performed, a charging amount calculation unit 20 that calculates an amount of charging per period that is charged in the storage capacitor SC during the switching period, and a determination unit 30 that determines the status of the storage capacitor SC based on the first voltage level, the second voltage level, the counted number of switchings, and the calculated amount of charging per period.

The present disclosure relates to a health check system for a storage capacitor that checks the capacitance of a storage capacitor charged by a DC-DC switching converter without an additional circuit and power loss.

In general, a memory system including memory devices and a memory controller operates by receiving power from the outside. Accordingly, when the supply of power to the memory system is unintentionally cut off, data being processed may be lost. For example, a main system may be a solid state drive (SSD) or elements within the SSD. The SSD is a semiconductor-based storage device and has a power loss protection integrated circuit that can supply emergency power so that data being processed is not lost even in an unintentional sudden power supply cut-off situation. In such a case, the power loss protection integrated circuit supplies power to a power management component such as a PMIC within the SSD to support stable storage of data in a NAND flash memory. The power loss protection integrated circuit is an integrated circuit configured to supply power to the main system in a steady situation where power is normally supplied from an external power source and simultaneously stores energy in a storage capacitor by using some of the power, and to supply emergency power to the main system by using the energy stored in the storage capacitor in an emergency power situation where the supply of power is cut off.

Since the energy required in the emergency power situation is proportional to the capacity of the storage capacitor and the performance degradation of the storage capacitor, such as a decrease in maximum capacitance, occurs according to an operating voltage, temperature, humidity, use time, and the like, it is necessary to regularly check the capacitance of the storage capacitor. Such a regular check is referred to as a capacitor status check or health check.

In general, since the capacitor status check is performed by discharging the storage capacitor by using a separate discharge circuit for a certain period of time to determine whether the voltage of the storage capacitor is higher than a threshold voltage, an additional discharge circuit is required. In addition, since power loss inevitably occurs during the discharging process, the voltage of the storage capacitor drops during the discharging process, and thus the energy of the storage capacitor is consumed, an energy shortage phenomenon occurs in an emergency power situation. Moreover, since a charging circuit needs to operate in order to re-charge the discharged storage capacitor, there is a problem in that efficiency performance is degraded.

The present disclosure was devised as a solution for solving such problems.

The storage capacitor SC to be checked in the health check system for a storage capacitor according to the embodiment of the present disclosure is a capacitor charged by a DC-DC switching converter. The DC-DC switching converter is a voltage converter that controls an output voltage through an ON/OFF operation of two power switches connected in series with each other, and includes a boost converter that boosts a DC input voltage and a buck converter that drops the DC input voltage.

The following description is given using a buck converter as an example; however, the present disclosure is not limited to a buck converter.

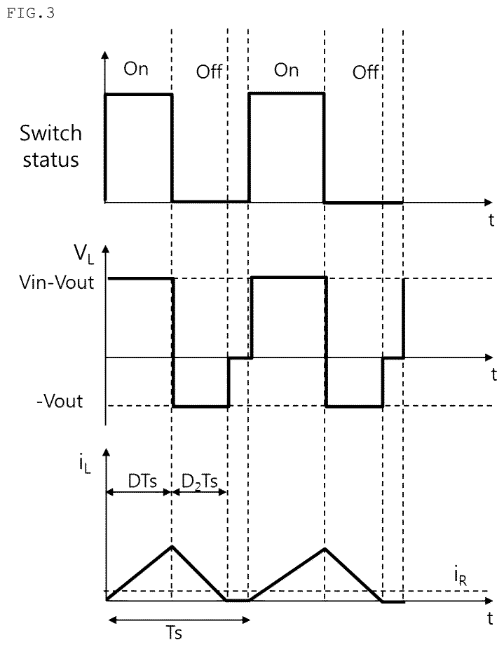

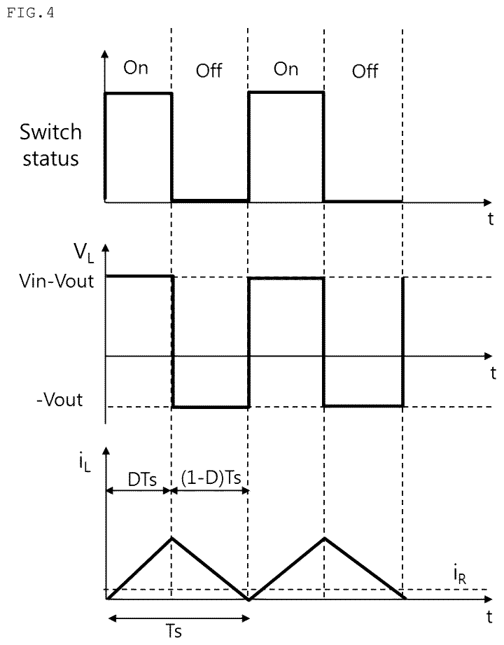

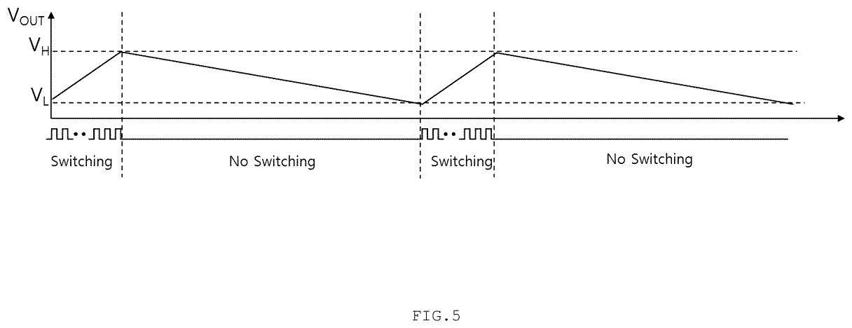

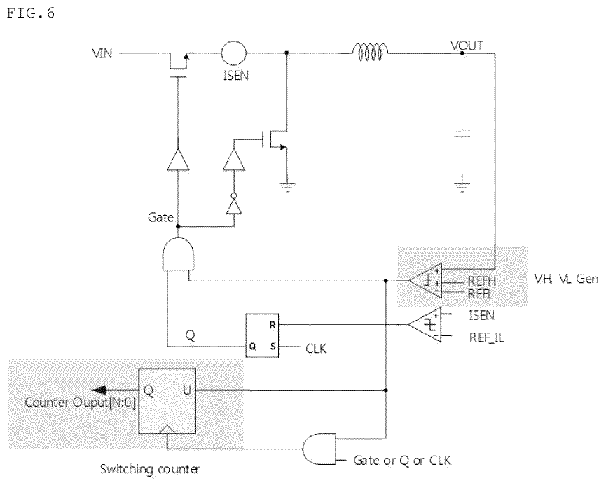

FIG. 2 is a diagram for explaining a storage capacitor charged by a buck converter in the related art, FIG. 3 is a diagram illustrating an inductor voltage and an inductor current according to each switch status when the buck converter in FIG. 2 charges the storage capacitor in a current discontinuous conduction mode, and FIG. 4 is a diagram illustrating an inductor voltage and an inductor current according to each switch status when the buck converter in FIG. 2 charges the storage capacitor in a current continuous conduction mode. FIG. 5 is a diagram illustrating a change in a charging voltage in a switching duration in which a switching operation of the buck converter in FIG. 2 is performed and a no-switching duration in which the switching operation is not performed.

Referring to FIG. 2, the storage capacitor SC can be charged by being electrically connected to the output terminal of the buck converter. The buck converter drops and outputs an input voltage Vi, by repeating a switching operation in a cycle of a continuous on and off switching operation of a switch, and the storage capacitor SC is charged based on an output voltage Vₒᵤₜ. The buck converter may include two power switches and an output inductor. Such a buck topology originates from a control method of the two power switches. The on/off control method provides a regulated output voltage and is synchronized in order to prevent the two power switches from being turned on at the same time. A high side power switch HS is directly connected to the input voltage of the circuit, and when the HS is turned on, current is supplied to a load through the HS. In such a case, a low side power switch LS is turned off, an inductor current increases, and an LC filter is charged. When the HS is turned off, the LS is turned on, and the charged current is supplied to the load. In such a case, the inductor current decreases, and the LC filter is discharged. As a result, when the two power switches are alternately and repeatedly turned on and off, the output voltage can be generated according to a duty ratio. The buck converter can operate in a discontinuous conduction mode (DCM) and a continuous conduction mode (CCM).

FIG. 3 illustrates a charging process in the DCM mode. In the DCM mode, since there is a status where an inductor current i_{L} is “0”, the operating status of the buck converter is divided into three durations. In a switching period Tₛ, when the switch is turned on, the inductor current increases and energy is accumulated (DTₛ duration), and when the switch is turned off, the accumulated energy is released and the inductor current decreases to “0” (D₂Tₛ duration). In the last duration where the inductor current is “0”, since no current flows to the inductor, discharging from the storage capacitor SC to the load is performed. Here, duty ratios D and D₂, an input/output voltage relationship Vₒᵤₜ/Vᵢₙ, peak current iₚₑₐₖ of the inductor, an amount Q_{D} of charging charged in the storage capacitor in the DTₛ duration, an amount Q_{D2} of charging charged in the storage capacitor in the D₂Tₛ duration, and an amount Q_{1period} of charging charged in the storage capacitor in the switching period Tₛ duration are determined as follows.

$$D = {V}_{out} \sqrt{\frac{2 Lf}{{R V}_{in} ( {V}_{in} - {V}_{out} )}} , {D}_{2} = \frac{1}{2} ( - D + \sqrt{{D}^{2} + \frac{8 L}{{RT}_{s}}} ) ,$$

$$\frac{{V}_{out}}{{V}_{in}} = \frac{D}{D + {D}_{2}} ,$$

$${i}_{peak} = \frac{{V}_{in} - {V}_{out}}{L} {DT}_{S} = \frac{{V}_{out}}{L} {D}_{2} {T}_{S} ,$$

$${Q}_{D} = \frac{{i}_{peak}}{2} {DT}_{S} ,$$

$${Q}_{D 2} = \frac{{i}_{peak}}{2} {D}_{2} {T}_{S} ,$$

$${Q}_{1 period} = \frac{{i}_{peak}}{2} ( D + {D}_{2} ) {T}_{S} .$$

In the above, in a steady state, the input voltage Vᵢₙ, the output voltage Vₒᵤₜ, the inductance L of the inductor, the duty ratio D, and the switching period Tₛ have fixed values.

FIG. 4 illustrates a charging process in the CCM mode. In the CCM mode, during the switching period Tₛ, the operating status of the buck converter is divided into a duration (DTₛ duration) in which when the switch is turned on, the inductor current i_{L} increases and energy is accumulated and a duration ((1−D)Tₛ duration) in which when the switch is turned off, the inductor current decreases to “0” as the accumulated energy is released. Here, the duty ratio D, the peak current iₚₑₐₖ of the inductor, the amount Q_{D} of charging charged in the storage capacitor in the DTₛ duration, the amount Q_{D2} of charging charged in the storage capacitor in the (1−D)Tₛ duration, and the amount Q_{1period} of charging charged in the storage capacitor in the switching period Ts duration are determined as follows.

$$\frac{{V}_{out}}{{V}_{in}} = D ,$$

$${i}_{peak} = \frac{{V}_{in} - {V}_{out}}{L} {DT}_{S} = \frac{{V}_{out}}{L} ( 1 - D ) {T}_{S} ,$$

$${Q}_{D} = \frac{{i}_{peak}}{2} {DT}_{S} ,$$

$${Q}_{D 2} = \frac{{i}_{peak}}{2} ( 1 - D ) {T}_{S} ,$$

$${Q}_{1 period} = \frac{{i}_{peak}}{2} {T}_{S} .$$

In the above, in a steady state, the input voltage Vᵢₙ, the output voltage Vₒᵤₜ, the inductance L of the inductor, the duty ratio D, and the switching period Tₛ have fixed values.

Referring to FIG. 5, when the level of the charging voltage for charging the storage capacitor SC is a first voltage level V_{L}, the buck converter boosts the level of the charging voltage to a second voltage level V_{H} by performing a switching operation in a switching duration. In a no-switching duration where the switching operation is stopped, the storage capacitor SC is naturally discharged. When the level of the charging voltage reaches the first voltage level through the natural discharging, the buck converter performs a switching operation to control the voltage by increasing the level of the charging voltage to the second voltage level. The first voltage level and the second voltage level, which are the criteria for starting and ending the switching operation, are preset for the voltage control of the buck converter.

The health check system for a storage capacitor according to the embodiment of the present disclosure determines the status of the storage capacitor SC in a switching duration without a separate artificial discharging process for the storage capacitor SC.

Specifically, the health check system for a storage capacitor according to the embodiment of the present disclosure may include the switching counter 10, the charging amount calculation unit 20, and the determination unit 30. The switching counter 10, the charging amount calculation unit 20, and the determination unit 30 may be directly implemented with hardware, implemented with a software module executed by hardware, or implemented with a combination thereof. The software module may also reside in a random access memory (RAM), a read only memory (ROM), an erasable programmable ROM (EPROM), an electrically erasable programmable ROM (EEPROM), a flash memory, a hard disk, a removable disk, a CD-ROM, or any form of a computer-readable recording medium well known in the technical field to which the present disclosure pertains.

The switching counter 10 calculates the number of switchings. The number of switchings is the number of times by which a switching operation is performed in a switching duration in which the switching operation is performed. That is, the number of switchings is the number of switching operations performed during the time for which a charging voltage changes from the first voltage level to the second voltage level. Since the switching operation performs a continuous On and Off operation during a switching period, the On/Off operation is regarded as one switching operation. For example, the number of switching operations is 2 in FIGS. 3 and 4. Since the switching operation is repeated according to the switching period, a value obtained by dividing the total time for which the charging voltage changes from the first voltage level to the second voltage level by the switching period can be calculated as the number of switchings. However, since this is merely an example, even though the number of switchings is counted in any method, the scope of the present disclosure needs not to be limited thereto.

The charging amount calculation unit 20 calculates the charging amount per period charged in the storage capacitor SC during the switching period. For example, the charging amount calculation unit 20 can calculate the charging amount per period based on the current i_{L} flowing through an inductor of the switching converter 10 according to the switching operation and the switching period Tₛ. Since the charging amount per period is equal to an area occupied by the inductor current i_{L} in the graph of the inductor current i_{L} according to time t of FIGS. 3 and 4, the charging amount calculation unit 20 can calculate the charging amount per period by detecting the inductor current according to time. Alternatively, in the case of the buck converter above, the charging amount Q_{1period} per period could be obtained based on the peak current iₚₑₐₖ of the inductor, and thus the charging amount per period can also be calculated.

The determination unit 30 determines the status of the storage capacitor SC. The status of the storage capacitor SC can be determined based on the first voltage level, the second voltage level, the counted number of switchings, and the calculated amount of charging per period.

In a first embodiment, the determination unit 30 can calculate the reference number of switchings according to the following Equation 1, and determine the storage capacitor SC to be in a steady state when the counted number of switchings satisfies the following Inequation 1.

$$SCr = \frac{Cr \times ( {V}_{H} - {V}_{L} )}{{Q}_{1 period}} \qquad [ Equation 1 ]$$

In Equation 1 above, SCr is the reference number of switchings, Cr is the preset capacitance of the storage capacitor SC, V_{H} is the second voltage level, V_{L} is the first voltage level, and Q_{1period} is the charging amount per period calculated by the charging amount calculation unit 20. Cr is the initial capacitance of the storage capacitor SC provided by a manufacturer that manufactures the storage capacitor SC, and the value of Cr can be preset. Accordingly, SCr corresponds to the number of switchings by which a switching operation is performed on the storage capacitor SC, which has not been deteriorated by repeated charging/discharging, while the voltage level is being controlled from the first voltage level to the second voltage level.

SCr×α≤SCc≤SCr×β [Inequation 1]

In Inequation 1 above, SCc is the number of switchings counted by the switching counter 10, α is a rational number equal to or less than 1, and β is a rational number equal to or greater than 1.

SCc corresponds to the actual number of switchings by which the switching operation is performed on the storage capacitor SC to be checked while the voltage level is being controlled from the first voltage level to the second voltage level. Accordingly, in the present embodiment, the normality or failure of the storage capacitor SC is determined based on the number of switchings by which the switching operation is performed while the voltage level is being controlled from the first voltage level to the second voltage level. Here, α and β are coefficients for determining a normal allowable range, and α can be set to 0.7 to 0.9 and β can be set to 1.1 to 1.3. For example, in a case where α is 0.8 and β is 1.2, when the number of switchings counted by the switching counter 10 is within the range of 80% to 120% of the reference number of switchings calculated by Equation 1 above, the storage capacitor SC to be checked is determined to be in a steady state, and when the counted number of switchings is out of the range, the storage capacitor SC to be checked is determined to be in a failure state. When the storage capacitor SC is open failure, the number of switchings counted by the switching counter 10 decreases, and when the storage capacitor SC is short failure, the number of switchings counted by the switching counter 10 increases. However, the coefficients α and β are not necessarily limited to the above range.

In a second embodiment, the determination unit 30 calculates the capacitance of the storage capacitor SC according to the following Equation 2, and when the calculated capacitance of the storage capacitor SC satisfies the following Inequation 2, the determination unit 30 can determine the storage capacitor SC to be in a steady state. In the second embodiment, the storage capacitor SC is determined based on energy required for the storage capacitor SC.

$$C = \frac{{Q}_{1 period} \times SCs}{{V}_{H} - {V}_{L}} \qquad [ Equation 2 ]$$

In Equation 2 above, C is the capacitance of the storage capacitor SC, V_{H} is the second voltage level, V_{L} is the first voltage level, Q_{1period} is the charging amount per period calculated by the charging amount calculation unit 20, and SCc is the number of switchings counted by the switching counter 10.

$$\frac{2 \times E}{{{V}_{L}}^{2}} \leq C \qquad [ Inequation 2 ]$$

In Inequation 2 above, E is the preset energy J of the storage capacitor SC and V_{L} is the first voltage level. E is energy required for the storage capacitor SC in preparation for an emergency power situation and is preset.

Accordingly, when the capacitance of the storage capacitor SC calculated by Equation 1 above sufficiently holds the energy required for the storage capacitor SC, the storage capacitor SC can be determined to be in a steady state.

In a third embodiment, the determination unit 30 can determine the steady state of the storage capacitor SC by combining the matters related to the first and second embodiments described above. First, the determination unit 30 calculates the reference number SCr of switchings according to Equation 1 above. Subsequently, the determination unit 30 calculates the required capacitance Cn of the storage capacitor SC by reflecting the energy E, which is required for the storage capacitor SC in preparation for an emergency power situation, according to the following Equation 3.

$$Cn = \frac{2 \times E}{{{V}_{L}}^{2}} \qquad [ Equation 3 ]$$

In Equation 3 above, Cn is the required capacitance of the storage capacitor SC, E is the preset energy J of the storage capacitor SC, and V_{L} is the first voltage level. The required capacitance Cn of the storage capacitor SC is the capacitance for accumulating the energy required in preparation for the emergency power situation.

Subsequently, “SCr×α”, which is the lower limit of the number of normal switchings for the storage capacitor SC of the first embodiment, is determined according to the following Equation 4 below. In such a case, “SCr×β”, which is the upper limit of the number of normal switchings, is determined by the reference number SCr of switchings calculated according to Equation 1 above and the coefficient β.

$$SCr \times α = \frac{Cn \times ( {V}_{H} - {V}_{L} )}{{Q}_{1 period}} \qquad [ Equation 4 ]$$

In Equation 4 above, Cn is the required capacitance of the storage capacitor SC, V_{H} is the second voltage level, V_{L} is the first voltage level, and Q_{1period} is the amount of charging per period calculated by the charging amount calculation unit 20.

Accordingly, when the number SCc of switchings counted by the switching counter 10 is equal to or greater than the value calculated according to Equation 4 above, and when the number SCc of switchings is equal to or less than the value of “SCr×β”, the storage capacitor SC can be determined to be in a steady state.

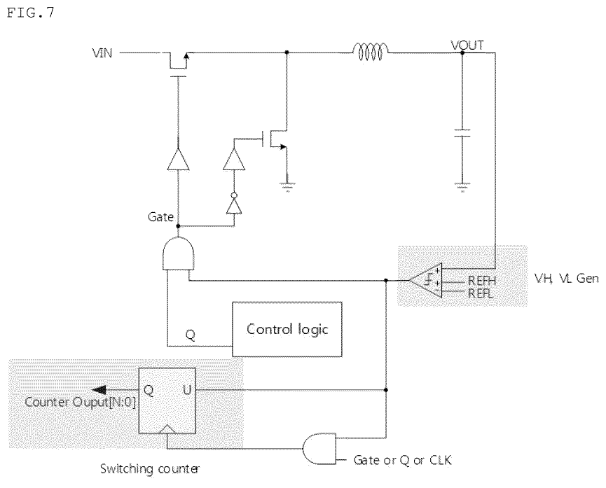

FIGS. 6 and 7 are exemplary circuit diagrams of the health check system for a storage capacitor according to the embodiment of the present disclosure.

With reference to FIGS. 6 and 7, the level of the charging voltage in the buck converter, that is, the first voltage level and the second voltage level can be preset, and the number of switchings of the buck converter can be counted.

Specifically, a circuit illustrated in FIG. 6 is an example of measuring the capacitance OUTPUT Capacitance of the storage capacitor by counting the number of switchings. Here, the buck converter control method generates a gate signal Gate for turning off a high side and turning on a low side when current information sensed on the high side reaches REF_IL set by an IC. The gate signal Gate is ANDed with the output VOUT of a hysteretic comparator that allows VOUT to be High only between REFH and REFL, so that VOUT is switched only between REFL and REFH. More precisely, VOUT is High from 0 to REFH, is Low from REFH to REFL, and is High below REFL. In such a case, since the output of the hysteretic comparator is High only in a switching duration, when this signal is used as U (Up enable) of a counter and the gate signal Gate is used as a clock, the counter can operate only in the duration from REFL to REFH. Accordingly, the capacitance can be calculated with the output of the counter.

A circuit illustrated in FIG. 7 is a comprehensive circuit of FIG. 6. FIG. 6 illustrates that the SR Latch type control logic for turning off the High side by comparing the High side sensing information and REF_IL can be implemented in a different way. For example, it is a method similar to constant on time for turning on the high side only for a certain amount of time.

In summary, according to the present disclosure, since the status of the storage capacitor SC can be checked without additional discharging, no voltage drop occurs, and thus power loss can be prevented. In addition, since no additional discharging circuit is required, the present disclosure can reduce the size of a circuit and can also be applied to any structure of a switching converter. In the related art, when additional discharging is performed in a no-switching duration, a voltage may drop to a lower level than a minimum output voltage. However, in the present disclosure, the lowest level is fixed to a minimum output voltage, so that the amount of energy can be stably maintained

Although the present disclosure has been described in detail through specific examples, this is for specifically explaining the present disclosure, the present disclosure is not limited thereto, and it is obvious that modifications or improvements can be made by those skilled in the art within the technical concept of the present disclosure.

All simple modifications or changes of the present disclosure fall within the scope of the present disclosure, and the specific protection scope of the present disclosure will be clarified by the appended claims.

What is claimed is:

1. A health check system for a storage capacitor that checks a capacitance of a storage capacitor charged by being electrically connected to an output terminal of a switching converter that, when a preset level of a charging voltage is a first voltage level, boosts the voltage level to a second voltage level by performing a switching operation according to a switching period, the health check system for a storage capacitor comprising:
a switching counter that counts the number of switchings by which the switching operation is performed in a switching duration in which the switching operation is performed;
a charging amount calculation unit that calculates an amount of charging per period that is charged in the storage capacitor during the switching period; and
a determination unit that determines a status of the storage capacitor based on the first voltage level, the second voltage level, the counted number of switchings, and the calculated amount of charging per period.

2. The health check system for a storage capacitor of claim 1, wherein the charging amount calculation unit calculates the charging amount per period based on current flowing through an inductor of the switching converter and the switching period.

3. The health check system for a storage capacitor of claim 1, wherein:
the determination unit calculates the reference number of switchings according to Equation 1 below, and
determines the storage capacitor to be in a steady state when the counted number of switchings satisfies Inequation 1 below:
$$SCr = \frac{Cr \times ( {V}_{H} - {V}_{L} )}{{Q}_{1 period}} \qquad [ Equation 1 ]$$
in Equation 1 above, SCr is the reference number of switchings, Cr is a preset capacitance of the storage capacitor, V_{H} is the second voltage level, V_{L} is the first voltage level, and Q_{1period} is a charging amount per period;
SCr×α≤SCc≤SCr×β [Inequation 1]
in Inequation 1 above, SCc is the counted number of switching, α is a rational number equal to or less than 1, and β is a rational number equal to or greater than 1.

4. The health check system for a storage capacitor of claim 3, wherein α is 0.7 to 0.9 and β is 1.1 to 1.3.

5. The health check system for a storage capacitor of claim 1, wherein:
the determination unit calculates the capacitance of the storage capacitor according to Equation 2 below, and
when the calculated capacitance of the storage capacitor satisfies Inequation 2 below, the determination unit determines the storage capacitor to be in a steady state:
$$C = \frac{{Q}_{1 period} \times SCs}{{V}_{H} - {V}_{L}} \qquad [ Equation 2 ]$$
in Equation 2 above, C is the capacitance of the storage capacitor, V_{H} is the second voltage level, V_{L} is the first voltage level, Q_{1period} is the charging amount per period, and SCc is the counted number of switchings;
$$\frac{2 \times E}{{{V}_{L}}^{2}} \leq C \qquad [ Inequation 2 ]$$
in Inequation 2 above, E is preset energy J of the storage capacitor and V_{L} is the first voltage level.

6. The health check system for a storage capacitor of claim 3, wherein:
the determination unit calculates a required capacitance of the storage capacitor according to Equation 3 below, and
“SCr×α” in Inequation 1 above is determined according to Equation 4 below:
$$Cn = \frac{2 \times E}{{{V}_{L}}^{2}} \qquad [ Equation 3 ]$$
in Equation 3 above, Cn is the required capacitance of the storage capacitor, E is preset energy J of the storage capacitor, and V_{L} is the first voltage level;
$$SCr \times α = \frac{Cn \times ( {V}_{H} - {V}_{L} )}{{Q}_{1 period}} \qquad [ Equation 4 ]$$
in Equation 4 above, Cn is the required capacitance of the storage capacitor, V_{H} is the second voltage level, V_{L} is the first voltage level, and Q_{1period} is the amount of charging per period.
